(19) United States
(12) Patent Application Publication
(10) Pub. No.: US 2022/0187664 A1
(43) Pub. Date: Jun. 16, 2022

(54) DISPLAY PANEL AND DEFECT REPAIRING METHOD OF SAME

(71) Applicant: SHENZHEN CHINA STAR OPTOELECTRONICS SEMICONDUCTOR DISPLAY TECHNOLOGY CO., LTD., Shenzhen (CN)

(72) Inventor: Jing ZHU, Shenzhen (CN)

(73) Assignee: SHENZHEN CHINA STAR OPTOELECTRONICS SEMICONDUCTOR DISPLAY TECHNOLOGY CO., LTD., Shenzhen (CN)

(21) Appl. No.: 16/760,505

(22) PCT Filed: Apr. 15, 2020
(86) PCT No.: PCT/CN2020/084951

§ 371 Date: Apr. 30, 2020

(30) Foreign Application Priority Data
Mar. 4, 2020 (CN) 202010142240.0

(51) Int. Cl. G02F 1/1362; G02F 1/1343; H01L 21/768; B23K 26/26

(52) U.S. Cl. CPC G02F 1/136263; G02F 1/134309; B23K 26/26; H01L 21/76894; G02F 1/136286

(57) ABSTRACT

A display panel and a defect repairing method of same are provided by this application. The display panel comprises a display area and a bezel area. The display area comprises a plurality of scan lines and a plurality of data lines. Each of a plurality of pixel electrodes is disposed in a pixel area surrounded by the scan lines and the data lines, including two trunk electrodes disposed in a shape of a cross. a common electrode disposed in a different layer from the pixel electrodes. The common electrode comprises a plurality of first electrode lines and a plurality of second electrode lines. a portion of the common electrode corresponding to one of the trunk electrodes is overlapped with the one of the trunk electrodes.

### BACKGROUND OF INVENTION

### Field of Invention

This application relates to the field of display technologies, and particularly relates to a display and a defect repairing method of same.

### Description of Prior Art

Liquid crystal displays (LCDs) are one of the most widely used flat-panel displays. High aperture ratio, narrow-bezel and uniform charging rate at high frequency are goals pursued by thin film transistor liquid crystal display (TFT-LCD) panel makers. Conventional pixel design mainly includes a plurality of gate lines, a plurality of data lines, a common electrode and a plurality of pixel electrodes etc. Among which, a common electrode (ACOM) is made to form a capacitor (Cst) between the common electrode and the pixel electrodes. To solve quality problems of TFT-LCD, such as flickering caused by leakage and other factors, there exists certain requirements for a capacitance of the capacitor (Cst). That is, the capacitance of the capacitor (Cst) cannot be too small. As a result, a width of the common electrode (ACOM) located in a bezel of the LCD is relatively wide, which goes against development of narrow-frame LCDs.

Therefore, defects existing in prior art need to be solved.

This application provides a display panel and a defect repairing method of the same which can solve the problem of wide bezels and easy occurrence of bright points of display panels in prior art.

### SUMMARY OF INVENTION

In order to solve the above problems, technical schemes provided by this application are as below:

A display panel is provided by this application, comprising a display area and a bezel area, wherein the display area comprises:

a plurality of scan lines extending horizontally;

a plurality of data lines extending longitudinally;

a plurality of pixel electrodes each disposed corresponding to a pixel area surrounded by the scan lines and the data lines, wherein each of the pixel electrodes comprises two trunk electrodes disposed in a shape of a cross;

a plurality of pixel driving components each configured to electrically connect one of the pixel electrodes to one of the scan lines and one of the data lines; and

a common electrode disposed in a different layer from the pixel electrodes, wherein the common electrode comprises a plurality of first electrode lines extending horizontally and a plurality of second electrode lines extending longitudinally;

wherein the first electrode lines and the second electrode lines are disposed corresponding to the trunk electrodes, and a portion of the common electrode corresponding to one of the trunk electrodes is overlapped with the one of the trunk electrodes.

In the display panel of this application, the first electrode lines are disposed in a same layer as the scan lines, and the second electrode lines are disposed in a same layer as the data lines.

In the display panel of this application, a dielectric layer is disposed between the first electrode lines and the second electrode lines, and each of the first electrode lines is electrically connected to one of the second electrode lines through a via hole provided in the dielectric layer.

In the display panel of this application, the plurality of first electrode lines are disposed in parallel, and the plurality of second electrode lines are disposed in parallel.

In the display panel of this application, a row scan driving circuits and a plurality of row scan driving bus lines are disposed in the bezel area.

In the display panel of this application, an orthographic projection on the display panel of a portion of the common electrode corresponding to one of the trunk electrodes is located in a range of an orthographic projection on the display panel of the one of the trunk electrodes.

A defect repairing method of a display panel is also provided, the method comprises steps of:

step S1, cutting a connecting portion of one of the data lines connected to one of the pixel driving components at a connecting site between the one of the data lines and the one of the pixel driving components by laser;

step S2, soldering one of the pixel electrodes to one of the second electrode lines at a position where the one of the pixel electrode overlaps with the one of the second electrode lines.

In the defect repairing method of the display panel of this application, after cutting one of the data lines away from the one of the pixel driving components, a width of a portion of the one of the data lines corresponding to a cutting site is greater than or equals to widths of other portions left of the one of the data lines.

In the defect repairing method of the display panel of this application, an insulating layer is disposed between the pixel electrodes and the second electrode lines, and the step S2 comprises steps of:

step S201, forming a soldering hole penetrating the one of the pixel electrodes and the insulating layer at a pre-set position where the one of the pixel electrodes overlaps with the one of the second electrode lines using laser;

step S202, laser exposing the pixel electrode located around the soldering hole to make the pixel electrode located around the soldering hole molten and then contact the one of the second electrode lines through the soldering hole.

To solve above-mentioned problems, a display panel is also provided by this application, comprising a display area and a bezel area, and the display area comprises:

a plurality of scan lines extending horizontally;

a plurality of data lines extending longitudinally;

a plurality of pixel electrodes each disposed corresponding to a pixel area surrounded by the scan lines and the data lines, each of the pixel electrode comprises two trunk electrodes disposed in a shape of a cross;

a plurality of pixel driving components each configured to electrically connect one of the pixel electrodes to one of the scan lines and one of the data lines;

and

a common electrode disposed in a different layer from the pixel electrodes, wherein the common electrode comprises a plurality of first electrode lines extending horizontally and a plurality of second electrode lines extending longitudinally, the first electrode lines and the second electrode lines intersect to form a network structure;

wherein the first electrode lines and the second electrode lines are disposed corresponding to the trunk electrodes, and a portion of the common electrode corresponding to one of the trunk electrodes is overlapped with the one of the trunk electrodes.

In the display panel of this application, the first electrode lines are disposed in a same layer as the scan lines, and the second electrode lines are disposed in a same layer as the data lines.

In the display panel of this application, a dielectric layer is disposed between the first electrode lines and the second electrode lines, and each of the first electrode lines is electrically connected to one of the second electrode lines through a via hole provided in the dielectric layer.

In the display panel of this application, the plurality of first electrode lines are disposed in parallel, and the plurality of second electrode lines are disposed in parallel.

In the display panel of this application, a row scan driving circuits and a plurality of row scan driving bus lines are disposed in the bezel area.

In the display panel of this application, an orthographic projection on the display panel of a portion of the common electrode corresponding to one of the trunk electrodes is located in a range of an orthographic projection on the display panel of the one of the trunk electrodes.

Advantageous effects of this application are as below: according to the display panel and the defect repairing method of the same provided by this application, by removing a common electrode (ACOM) acting as a reference capacitor (Cst Reference) from a bezel area of display panels in prior art, and configuring the common electrode of double-layer construction in the display area and configuring the common electrode at a position of cross-shaped trunk electrodes of the pixel electrode, an aperture region of the pixel is not necessary to be occupied, bezel size can be reduced, at the same time aperture ratio of the pixel can be increased. In addition, according to this application, by soldering a corresponding pixel electrode of a pixel where bright points occur to a common pixel electrode, negative phenomena that bright spots occur in pixels due to factors such as manufacturing process could be avoided.

### BRIEF DESCRIPTION OF DRAWINGS

Technical scheme and other advantageous effects of the application will be obvious with detailed description of specific embodiments of this application in combination with drawings as below.

FIG. 1 is a structural schematic view of a display panel provided by embodiments of this application.

FIG. 2 is a structural schematic view of a bezel area of the display panel in prior art.

FIG. 3 is a structural schematic view of a bezel area of a display panel of this application.

FIG. 4 is a structural schematic view of a common electrode provided by embodiments of this application.

FIG. 5 is a flowchart of a defect repairing method of a display panel provided by embodiments of this application.

FIG. 6 is a schematic view of a defect repairing of a display panel provided by embodiments of this application.

### DETAILED DESCRIPTION OF PREFERRED EMBODIMENTS

The technical schemes of this application will be described clearly and completely below in combination with the drawings in the embodiments of this application. Obviously, the described embodiments are only part of the embodiments of this application, not all of them. A person having ordinary skill in the art may obtain other embodiments based on the embodiments provided in this application without making any creative effort, which all belong to the scope of the present disclosure.

In description of this application, it is to be understood that direction or position relationship indicated by terms “longitudinal”, “horizontal”, “length”, “width”, “up”, “down”, “front”, “back”, “left”, “right”, “vertical”, “horizontal” is based on direction or position relationship shown in the drawings, only for the convenience of describing this application and simplifying the description. It does not indicate or imply that the device or element referred to must have a specific orientation, be constructed and operated in a specific orientation, so it cannot be understood as a limitation of this application. Besides, the terms “first”, “second” and “third” in the application are used for descriptive purposes only, and cannot be understood as indicating or implying relative importance or implying numbers of indicated technical features. Thus, a feature defined as “first” and “second” may explicitly or implicitly includes one or more than one such features. In the description of this application, “a plurality of” means two or more than two, unless otherwise specified. In this application, “/” means “or”.

This application may repeat reference numbers and/or reference letters in different examples for the purpose of simplification and clarity, which does not indicate relationship between various embodiments and/or configurations discussed itself.

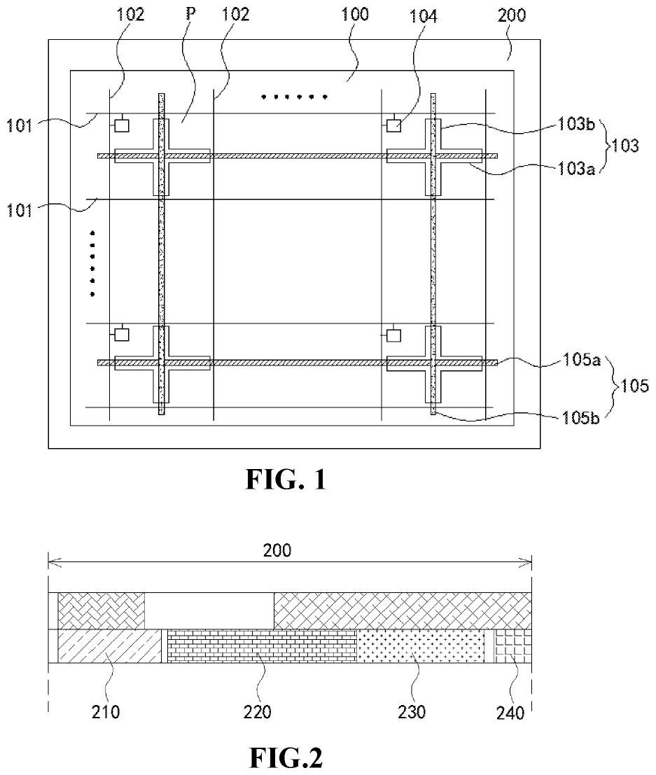

Please refer to FIG. 1, FIG. 1 is a structural schematic view of a display panel provided by embodiments of this application. The display panel comprises a display area 100 and a bezel area 200. The display panel corresponding to the display area comprises a plurality of scan lines 101 extending horizontally; a plurality of data lines 102 extending longitudinally; a plurality of pixel areas P surrounded by the scan lines 101 and the data lines 102; a plurality of pixel electrodes 103 each disposed corresponding to one of the pixel areas P, each of the pixel electrode 103 comprises two trunk electrodes disposed in a shape of a cross; a plurality of pixel driving components 104 each configured to electrically connect one of the pixel electrodes 103 to one of the scan lines 101 and one of the data lines 102; and a common electrode 105 disposed in a different layer from the pixel electrode 103, wherein the common electrode 105 comprises a plurality of first electrode lines 105a extending horizontally and a plurality of second electrode lines 105b extending longitudinally.

Wherein the first electrode lines 105a and the second electrode lines 105b are disposed corresponding to the trunk electrodes of the pixel electrode 103, and each of the trunk electrodes includes a horizontal trunk electrode 103a disposed horizontally and a longitudinal trunk electrode 103b disposed longitudinally. The horizontal trunk electrode 103a and the longitudinal trunk electrode 103b intersect in a cross.

A portion of the common electrode 105 corresponding to one of the trunk electrodes is overlapped with the one of the trunk electrodes. That is to say, a portion of the first electrode lines 105a corresponding to one of the horizontal trunk electrode 103a is overlapped with the one of the horizontal trunk electrode 103a, and a portion of the second electrode lines 105a corresponding to one of the longitudinal trunk electrode 103b is overlapped with the one of the longitudinal trunk electrode 103b. Generally due to different designs of the pixel electrode domains, a junction area of different domains in the middle of the pixel electrode (that is an area corresponding to the trunk electrode) appears to be a dark pattern area, which does not contribute to transmittance and aperture ratio of the pixel electrode. In this embodiment, by removing a common electrode (ACOM) from a bezel area of a display panel in prior art, and configuring the common electrode (CF-COM) at a position inside the display area corresponding to the cross-shaped trunk electrodes, an aperture region of the pixel is not necessary to be occupied, bezel size can be reduced, and at the same time, aperture ratio of the pixel can be increased. As a level of the common electrode (CF-COM) becomes a reference electrode of liquid crystals rotation, there is no need to worry about light leakage.

Wherein the first electrode lines 105a are disposed in a same layer as the scan lines 101, and the second electrode lines 105b are disposed in a same layer as the data lines 102.

Furthermore, the first electrode lines 105a are manufactured within a same mask process using a same material as the scan lines 101, and the second electrode lines 105b are manufactured within a same mask process by a same material as the data lines 102.

In this embodiment, the common electrode 105 is used to form a capacitor (Cst) with the pixel electrodes 103. An orthographic projection on the display panel of a portion of the common electrode 105 corresponding to one of the trunk electrodes is located in a range of an orthographic projection on the display panel of the one of the trunk electrodes. So that the common electrode 105 will not affect an aperture region of the pixels.

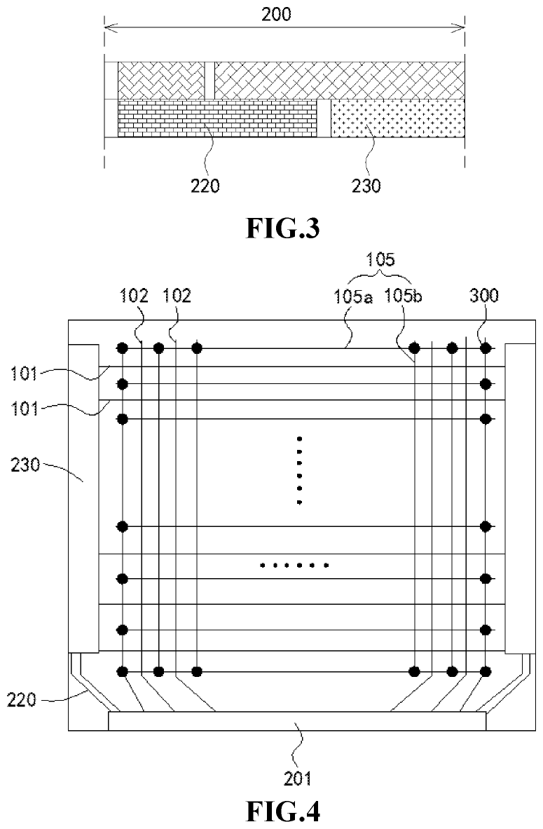

In combination with FIG. 2 and FIG. 3, FIG. 2 is a structural schematic view of a bezel area of a display panel in prior art and FIG. 3 is a structural schematic view of a bezel area of a display panel of this application. A common electrode (namely, C-COM) 210, a plurality of GOA bus lines (namely, row scan driving bus lines) 220, a GOA circuit (namely, row scan driving circuit) 230 and a common electrode (namely, A-COM) 240 are disposed in a bezel area 200 of a display panel in prior art. Only a plurality of GOA bus lines 200 and a GOA circuit 230 are disposed in a bezel area 200 of a display panel according to this application. As the common electrode (namely, A-COM) 240 is removed according to this application and the common electrode (namely, C-COM) 210 is moved to a position of the display area where the trunk electrodes locate, a bezel of the display panel according to this application could be significantly reduced.

In combination to FIG. 4, FIG. 4 is a structural schematic view of a common electrode provided by embodiments of this application. The first electrode lines 105a and the second electrode lines 105b intersect to form a network structure. A dielectric layer is disposed between the first electrode lines 105a and the second electrode lines 105b, and each of the first electrode lines 105a is electrically connected to one of the second electrode lines 105b through a via hole 300 provided in the dielectric layer. Wherein the plurality of first electrode lines 105a are disposed in parallel horizontally, and the plurality of second electrode lines 105b are disposed in parallel longitudinally. So that a structure of the common electrode 105 is relatively reliable, there is no need to worry about picture quality problems induced by coupling.

The bezel area 200 of the display panel includes a bonding area. A chip on film (COF) 201 is bonded in the bonding area. Each of the data lines 102 and each of the first electrode lines 105a is electrically connected to the chip on Film 201 respectively.

In one embodiment, the pixel electrode 103 further comprises a plurality of branch electrodes each connected to the trunk electrodes. There is no restriction here.

In this embodiment, a pixel structure of the display panel is defined as a 4 domains structure while in other embodiments, the pixel structure of the display panel can be defined as a 8 domains structure and so on.

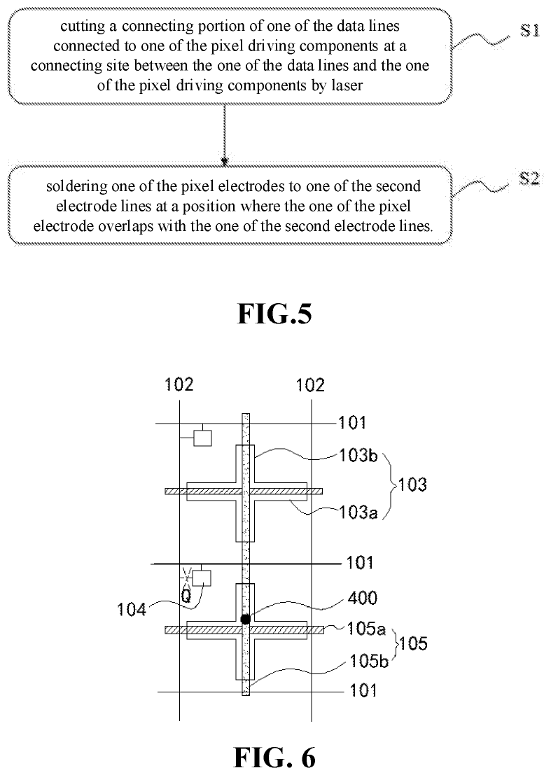

As shown in FIG. 5, a defect repairing method of the display panel provided in the above-mentioned embodiments of this application is also provided. The display panel is liquid crystal display panel, negative phenomena such as bright point etc. can easily be induced in pixels of the display panel due to factors such as manufacturing processes, affecting quality of the display panel. The defect repairing method of the display panel provided by this application can effectively repair the defects. In combination of what is illustrated in FIG. 5 and FIG. 6, the defect repairing method of the display panel includes steps of:

step S1, cutting a connecting portion of one of the data lines 102 connected to one of the pixel driving components 104 at a connecting site between the one of the data lines 102 and the one of the pixel driving components 104 by laser.

Wherein after cutting the one of the data lines 102 away from the one of the pixel driving components 104, a width of a portion of the one of the data lines 102 corresponding to a cutting site Q is greater than or equals to widths of other portions left of the one of the data lines 102. In this way, damages to the data lines 102 during the cutting process which may further causes disconnecting risk etc. could be avoided.

It can be understood that the above-mentioned steps only cut the pixel driving component corresponding to the pixel where negative phenomena such as bright points occur away from the data line to which the pixel driving component is connected, so as to conduct repairing on the pixel where the bright point occurs.

step S2, soldering the one of the pixel electrodes 103 to the one of the second electrode lines 105b at a position where the one of the pixel electrode 103 overlaps with the one of the second electrode lines 105b.

Specifically, an insulating layer is disposed between the pixel electrodes 103 and the second electrode lines 105b, and the step S2 comprises steps of:

step S201, forming a soldering hole 400 penetrating the one of the pixel electrodes 103 and the insulating layer at a pre-set position where the one of the pixel electrodes 103 overlaps with the one of the second electrode lines 105b by laser;

step S202, laser exposing the pixel electrode 103 located around the soldering hole 400 to make the pixel electrode 103 located around the soldering hole 400 molten and then contact the one of the second electrode lines 105b through the soldering hole 400.

As the pixel electrode 103 is welded to the common electrode 105 so that the pixel electrode 103 and the common electrode form a short circuit, that is to say, a potential of the pixel electrode 103 is equal to a potential of the common electrode 105, so that liquid crystals in a corresponding area of the pixel electrode do not deflect, namely a dark state, that is, the pixel where negative phenomena of bright spots occur is repaired and becomes a dark state.

In view of this, according to the display panel provided by this application, by removing a common electrode acting as a reference capacitor (Cst Reference) from a bezel area of display panels in prior art, and configuring the common electrode of double-layer construction in the display area and configuring the common electrode at a position of cross-shaped trunk electrodes of the pixel electrode, an aperture region of the pixel is not necessary to be occupied, bezel size can be reduced, at the same time aperture ratio of the pixel can be increased. According to the defect repairing method of the display panel of this application, by soldering the pixel electrode corresponding to the pixel where bright points occur to the common electrode, the potential of the pixel electrode becomes equal to the potential of the common electrode, so that liquid crystals corresponding to the pixel electrode does not deflect, namely a dark state, negative phenomena that bright spots occur in pixels due to factors such as manufacturing process could be avoided.

In conclusion although the application has been disclosed as above in the preferred embodiments, the above preferred embodiments are not used to limit the application. A person having ordinary skill in the art can make various changes and refinements within the spirit and scope of the application. Therefore, the protection scope of the application is subject to the scope defined in the claims.

What is claimed is:

1. A display panel comprising a display area and a bezel area, wherein the display area comprises:
a plurality of scan lines extending horizontally;
a plurality of data lines extending longitudinally;
a plurality of pixel electrodes each disposed corresponding to a pixel area surrounded by the scan lines and the data lines, wherein each of the pixel electrodes comprises two trunk electrodes disposed in a shape of a cross;
a plurality of pixel driving components each configured to electrically connect one of the pixel electrodes to one of the scan lines and one of the data lines; and
a common electrode disposed in a different layer from the pixel electrodes, wherein the common electrode comprises a plurality of first electrode lines extending horizontally and a plurality of second electrode lines extending longitudinally;
wherein the first electrode lines and the second electrode lines are disposed corresponding to the trunk electrodes, and a portion of the common electrode corresponding to one of the trunk electrodes is overlapped with the one of the trunk electrodes.

2. The display panel of claim 1, wherein the first electrode lines are disposed in a same layer as the scan lines, and the second electrode lines are disposed in a same layer as the data lines.

3. The display panel of claim 2, wherein a dielectric layer is disposed between the first electrode lines and the second electrode lines, and each of the first electrode lines is electrically connected to one of the second electrode lines through a via hole provided in the dielectric layer.

4. The display panel of claim 3, wherein the plurality of first electrode lines are disposed in parallel, and the plurality of second electrode lines are disposed in parallel.

5. The display panel of claim 1, wherein a row scan driving circuit and a plurality of row scan driving bus lines are disposed in the bezel area.

6. The display panel of claim 1, wherein an orthographic projection on the display panel of a portion of the common electrode corresponding to one of the trunk electrodes is located in a range of an orthographic projection on the display panel of the one of the trunk electrodes.

7. A defect repairing method of the display panel of claim 1, wherein the method comprises steps of:
step S1, cutting a connecting portion of one of the data lines connected to one of the pixel driving components at a connecting site between the one of the data lines and the one of the pixel driving components by laser;
step S2, soldering one of the pixel electrodes to one of the second electrode lines at a position where the one of the pixel electrode overlaps with the one of the second electrode lines.

8. The defect repairing method of the display panel of claim 7, wherein after cutting one of the data lines away from the one of the pixel driving components, a width of a portion of the one of the data lines corresponding to a cutting site is greater than or equals to widths of other portions left of the one of the data lines.

9. The defect repairing method of the display panel of claim 7, wherein an insulating layer is disposed between the pixel electrodes and the second electrode lines, and the step S2 comprises steps of:
step S201, forming a soldering hole penetrating the one of the pixel electrodes and the insulating layer at a pre-set position where the one of the pixel electrodes overlaps with the one of the second electrode lines by laser;
step S202, laser exposing the pixel electrode located around the soldering hole to make the pixel electrode located around the soldering hole molten and then contact the one of the second electrode lines through the soldering hole.

10. A display panel comprising a display area and a bezel area, wherein the display area comprises:
a plurality of scan lines extending horizontally;
a plurality of data lines extending longitudinally;
a plurality of pixel electrodes each disposed corresponding to a pixel area surrounded by the scan lines and the data lines, wherein each of the pixel electrodes comprises two trunk electrodes disposed in a shape of a cross;
a plurality of pixel driving components each configured to electrically connect one of the pixel electrodes to one of the scan lines and one of the data lines; and
a common electrode disposed in a different layer from the pixel electrodes, wherein the common electrode comprises a plurality of first electrode lines extending horizontally and a plurality of second electrode lines extending longitudinally, the first electrode lines and the second electrode lines intersect to form a network structure;
wherein the first electrode lines and the second electrode lines are disposed corresponding to the trunk electrodes, and a portion of the common electrode corresponding to one of the trunk electrodes is overlapped with the one of the trunk electrodes.

11. The display panel of claim 10, wherein the first electrode lines are disposed in a same layer as the scan lines, and the second electrode lines are disposed in a same layer as the data lines.

12. The display panel of claim 11, wherein a dielectric layer is disposed between the first electrode lines and the second electrode lines, and each of the first electrode lines is electrically connected to one of the second electrode lines through a via hole provided in the dielectric layer.

13. The display panel of claim 12, wherein the plurality of first electrode lines are disposed in parallel, and the plurality of second electrode lines are disposed in parallel.

14. The display panel of claim 10, wherein a row scan driving circuit and a plurality of row scan driving bus lines are disposed in the bezel area.

15. The display panel of claim 10, wherein an orthographic projection on the display panel of a portion of the common electrode corresponding to one of the trunk electrodes is located in a range of an orthographic projection on the display panel of the one of the trunk electrodes.
